(19) United States
(12) Patent Application Publication
(10) Pub. No.: US 2010/0136775 A1
(43) Pub. Date: Jun. 3, 2010

(54) METHOD OF MANUFACTURING THIN-FILM TRANSISTOR SUBSTRATE

(75) Inventors: Seung-Ha CHOI, Sihyeung-si (KR); Sang-Gab KIM, Seoul (KR); Bong-Kyu SHIN, Bucheun-si (KR); Sang-Uk LIM, Cheonan-si (KR); Jin-Ho JU, Seoul (KR); Sung-Hoon YANG, Seoul (KR); Sang-Woo WHANGBO, Seoul (KR); Jae-Ho CHOI, Seoul (KR); Ki-Yeup LEE, Seoul (KR); Yun-Jong YEO, Seoul (KR); Shin-Il CHOI, Seoul (KR); Dong-Ju YANG, Seoul (KR); Hong-Kee CHIN, Suwon-si (KR); Yu-Gwang JEONG, Yongin-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/607,567

(22) Filed: Oct. 28, 2009

(30) Foreign Application Priority Data
Dec. 2, 2008 (KR) 10-2008-0121228

(51) Int. Cl. H01L 21/28

(52) U.S. Cl. 438/585; 257/E21.19

(57) ABSTRACT

Provided is a method for manufacturing a thin-film transistor substrate, in which the etching characteristics of an insulating film and a passivation layer are enhanced. The insulating film and the passivation layer are deposited by low temperature chemical vapor deposition. The method includes disposing a gate wiring on an insulating substrate; disposing a gate insulating film on the gate wiring; disposing a data wiring on the gate insulating film; disposing a passivation layer on the data wiring; and forming a contact hole by etching at least one of the gate insulating film and the passivation layer, wherein at least one of the gate insulating film and the passivation layer is disposed at a temperature of about 280° C. or below, and the forming of the contact hole is performed at a pressure of about 60 mT or below.

This application claims priority to Korean Patent Application No. 10-2008-0121228, filed on Dec. 2, 2008, and all the benefits accruing therefrom under 35 U.S.C. §119, the contents of which in its entirety are herein incorporated by reference.

### BACKGROUND OF THE INVENTION

1. Field of the Invention

The present invention relates to a method of manufacturing a thin-film transistor (“TFT”) substrate, and more particularly, to a method of manufacturing a TFT substrate, in which etching characteristics of an insulating film and a passivation layer deposited by low-temperature chemical vapor deposition are enhanced.

2. Description of the Related Art

As modern society becomes more dependent on sophisticated information and communication technology, the markets' desire for larger and thinner displays is growing. In particular, since conventional cathode ray tubes (“CRTs”) have failed to fully satisfy these market needs, the demand for flat panel displays (“FPDs”), such as plasma display panels (“PDPs”), plasma address liquid crystal display panels (“PALCs”), liquid crystal displays (“LCDs”), and organic light emitting diodes (“OLEDs”), is exploding.

Of these FPDs, the LCD includes a lower panel having an array of TFTs, an upper panel facing the lower panel, with a liquid crystal layer interposed between the lower and upper panels. The LCD displays an image by controlling the intensity of an electric field applied to the liquid crystal layer. An LCD includes a display panel having an upper panel and a lower panel. Since a display panel is non-self-luminous, it is desirable to use light sources to provide light thereto in order to display an image. The display panel displays an image by controlling the transmittance of light received from the light sources.

Meanwhile, efforts are continuously being made to enhance the performance and production efficiency of LCDs. In particular, efforts are being made to prevent defects and extend useful life of equipment in order to enhance productivity. As part of these efforts, a technology for performing chemical vapor deposition (CVD) at a low temperature is being developed. Here, “low temperature” denotes approximately about 280° C. or below.

Deposition at such a low temperatures can advantageously extend the useful life of equipment, increase durability of internal parts, and be performed at the same temperature as that used in other processes. However, too low a deposition temperature causes a film to become porous and inferior in uniformity and chemical resistance. These problems affect a subsequent ashing process, thereby degrading etching characteristics of an insulating film and a passivation layer that are deposited in the TFT.

### BRIEF SUMMARY OF THE INVENTION

Aspects of the present invention provide a method of manufacturing a thin-film transistor substrate, in which etching characteristics of an insulating film and a passivation layer deposited by low-temperature chemical vapor deposition are enhanced.

Aspects of the present invention also provide a liquid crystal display including a display panel, which does not have stains thereon even when using a non-ground glass substrate.

However, aspects of the present invention are not restricted to the ones set forth herein. The above and other aspects of the present invention will become more apparent to one of ordinary skill in the art to which the present invention pertains by referencing the detailed description of the present invention given below.

According to an aspect of the present invention, there is provided a method of manufacturing a TFT substrate. The method includes disposing a gate wiring on an insulating substrate; disposing a gate insulating film on the gate wiring; disposing a data wiring on the gate insulating film; disposing a passivation layer on the data wiring; and forming a contact hole by etching at least one of the gate insulating film and the passivation layer, wherein at least one of the gate insulating film and the passivation layer is disposed at a temperature of about 280° C. or below, and the forming of the contact hole is performed at a pressure of about 60 millitorr (“mT”) or below.

According to another aspect of the present invention, there is provided a method of manufacturing a TFT substrate. The method includes disposing a gate wiring on an insulating substrate; disposing a gate insulating film on the gate wiring; disposing a data wiring on the gate insulating film; disposing a passivation layer on the data wiring; and forming a contact hole by etching at least one of the gate insulating film and the passivation layer, wherein at least one of the gate insulating film and the passivation layer is disposed at a temperature of about 280° C. or below, and a volume ratio (H₂/SiH₄) of hydrogen gas to silane gas is about 0.33 to about 1.

### BRIEF DESCRIPTION OF THE DRAWINGS

The above and other aspects, advantages, and features of the invention will become more apparent by describing in detail exemplary embodiments thereof with reference to the attached drawings, in which:

FIG. 1 is an exemplary layout diagram of a TFT substrate manufactured by using a manufacturing method according to the present invention; FIG. 2A is an exemplary cross-sectional view of the TFT substrate taken along the line A-A′ of FIG. 1;

FIG. 2B is an exemplary cross-sectional view of the TFT substrate taken along the line B-B′ of FIG. 1;

FIGS. 3A through 7B are exemplary cross-sectional views for sequentially detailing processes included in a method of manufacturing the TFT substrate of FIG. 1 according to the present invention; and

FIGS. 8A through 13B are exemplary cross-sectional views for sequentially explaining processes included in a method of manufacturing a TFT substrate according to the present invention.

### DETAILED DESCRIPTION OF THE INVENTION

Aspects, advantages, and features of exemplary embodiments of the invention and methods of accomplishing the same may be understood more readily by reference to the following detailed description of embodiments and the accompanying drawings. The exemplary embodiments of the invention may, however, may be embodied in many different forms, and should not be construed as being limited to the embodiments set forth herein. Rather, these embodiments are provided so that this disclosure will be thorough and complete and will fully convey the concept of the invention to those skilled in the art, and the exemplary embodiments of the invention will only be defined by the appended claims. Like reference numerals refer to like elements throughout the specification.

It will be understood that when an element or layer is referred to as being “on” or “connected to” another element or layer, the element or layer can be directly on or connected to another element or layer or intervening elements or layers. In contrast, when an element is referred to as being “directly on” or “directly connected to” another element or layer, there are no intervening elements or layers present. As used herein, the term “and/or” includes any and all combinations of one or more of the associated listed items.

It will be understood that, although the terms first, second, third, and the like, can be used herein to describe various elements, components, regions, layers and/or sections, these elements, components, regions, layers and/or sections should not be limited by these terms. These terms are only used to distinguish one element, component, region, layer, or section from another region, layer or section. Thus, a first element, component, region, layer, or section discussed below could be termed a second element, component, region, layer, or section without departing from the teachings of the exemplary embodiments of the invention.

Spatially relative terms, such as “below,” “lower,” “upper” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “lower” relative to other elements or features would then be oriented “above” relative to the other elements or features. Thus, the exemplary term “below” can encompass both an orientation of above and below. The device can be otherwise oriented (rotated 90 degrees or at other orientations) and the spatially relative descriptors used herein interpreted accordingly.

As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation can result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

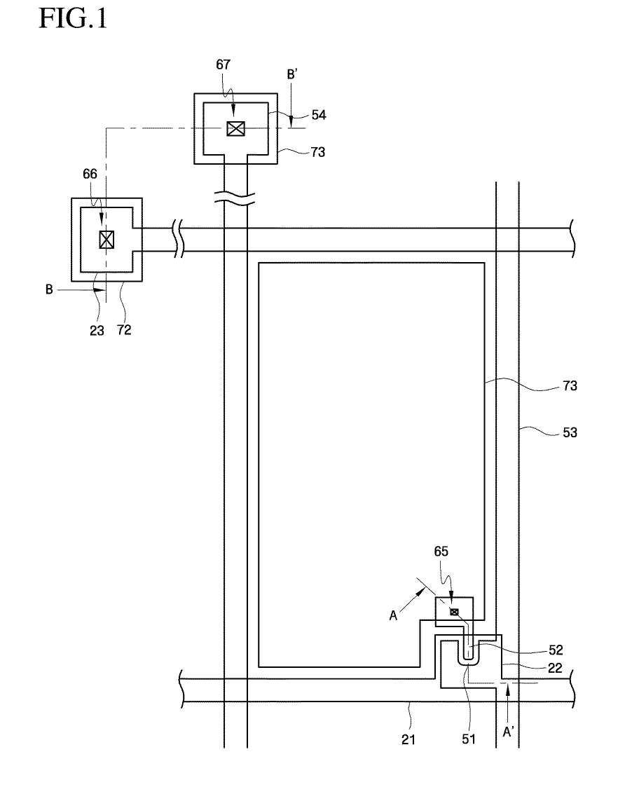

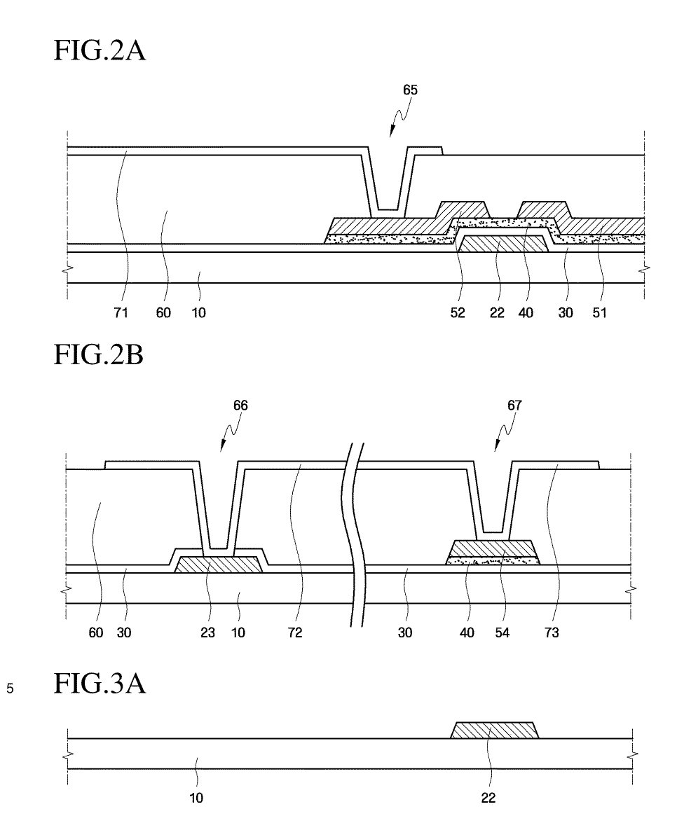

Hereinafter, a thin-film transistor (TFT) substrate manufactured by using a manufacturing method according to the present invention will be described in detail with reference to FIGS. 1 through 2B. FIG. 1 is a layout diagram of the TFT substrate manufactured by using the manufacturing method according to the present invention. FIG. 2A is a cross-sectional view of the TFT substrate taken along the line A-A′ of FIG. 1. FIG. 2B is a cross-sectional view of the TFT substrate taken along the line B-B′ of FIG. 1.

Referring to FIGS. 1 and 2A, a gate line 21 is disposed on an insulating substrate 10, which may be made of transparent glass. The gate line 21 generally extends in a horizontal direction and delivers a gate signal. One gate line 21 is allocated to each pixel. A gate electrode 22 protrudes from an end portion of the gate line 21, and a gate extension portion 23 is disposed at a tip end of the gate line 21.

Various gate metal patterns (not shown) may also be disposed on the insulating substrate 10. The gate metal patterns and the gate line 21 may be disposed in the same plane by the same process or by different processes if desired. The gate metal patterns may form circuit units such as a gate driver and a data driver. The gate line 21, the gate electrode 22, and the gate metal patterns are referred to as gate wirings. In the following description of the present invention, the gate wirings may encompass all wirings disposed by the same process as that for the gate line 21, the gate electrode 22, and the gate metal patterns.

The gate wirings may comprise aluminum (e.g., aluminum and an aluminum alloys), silver (e.g., silver and a silver alloy), copper (e.g., copper and a copper alloy), molybdenum (e.g., molybdenum and a molybdenum alloy), chrome (Cr), titanium (Ti) or tantalum (Ta).

A gate insulating film 30, which may be made of silicon nitride (SiNₓ) or silicon oxide (SiOₓ), is disposed on the gate wirings.

A semiconductor layer 40 is disposed on the gate insulating film 30 and made of hydrogenated amorphous silicon, polycrystalline silicon, or an oxide semiconductor. The oxide semiconductor is generally a metal oxide semiconductor.

A data line 53 generally extends in a perpendicular direction (e.g., a vertical direction) to cross the gate line 21 and delivers a data signal. A source electrode 51 protrudes from an end portion of the data line 53 towards a drain electrode 52, and a data extension portion 54 is disposed at a tip end of the data line 53.

Various data metal patterns (not shown) may also be disposed on the insulating substrate 10. The data metal patterns and the data line 53 may be disposed in the same plane by the same process. The data metal patterns may form circuit units such as the gate driver and the data driver. The data line 53, the data extension portion 54, and the data metal patterns are referred to as data wirings. In the following description of the present invention, the data wirings may encompass all wirings disposed by the same process as that for the data line 53, the source electrode 51, the drain electrode 52, and the data metal patterns.

The data wirings may be made of chrome, molybdenum-based metal, or refractory metal such as tantalum and titanium.

The source electrode 51 overlaps at least a part of the semiconductor layer 40. The drain electrode 52 faces the source electrode 51. The drain electrode 52 and the source electrode 51 are disposed on the gate electrode 22 and overlaps at least a part of the semiconductor layer 40. Depending on the manufacturing process, the semiconductor layer 40 may be completely overlapped by the data wirings (e.g., the data line 53 or the data extension portion 54). The semiconductor layer 40 can be manufactured using any method or can be manufactured in any form as long as at least part thereof is overlapped by each of the source electrode 51 and the drain electrode 52 to form a channel region between the source electrode 51 and the drain electrode 52.

The gate electrode 22, the source electrode 51, and the drain electrode 52 form three terminals of a TFT and function as the switching device.

A passivation layer 60 is disposed on the data wirings and on an exposed portion of the semiconductor layer 40. The passivation layer 60 can comprise an inorganic material such as silicon nitride or silicon oxide, an organic material having photosensitivity and superior planarization characteristics, or a low-k insulating material such as amorphous silicon, carbon and oxygen (a-Si:C:O) or amorphous silicon, oxygen and fluorine (a-Si:O:F).

The passivation layer 60 may comprise a lower inorganic film and an upper organic film in order to protect the exposed portion of the semiconductor layer 40 while taking advantage of the superior characteristics of the organic film. Further, a red, green or blue color filter layer may be used as the passivation layer 60.

First through third contact holes 65 through 67 are formed in the passivation layer 60. A pixel electrode 71 is physically and electrically connected to the drain electrode 52 via the first contact hole 65 to receive a data signal and a control voltage.

Referring to FIG. 2B, the gate extension portion 23 is connected to a first connecting electrode 72 by the second contact hole 66, and the data extension portion 54 is connected to a second connecting electrode 73 by the third contact hole 67. The first connecting electrode 72 and the second connecting electrode 73 connect the gate metal patterns (not shown) and the data metal patterns (not shown), which are disposed in different planes.

Specifically, the gate extension portion 23 and the data extension portion 54 illustrated in FIG. 2B may be an example of the gate metal pattern and an example of the data metal pattern, respectively. Numerous gate and data metal patterns, such as the gate extension portion 23 and the data extension portion 54, may be disposed on the insulating substrate 10 with the gate insulating film 30 disposed therebetween and forms part of a circuit. Here, the gate metal patterns may be connected to the data metal patterns by connecting electrodes (not shown), and the first and second connecting electrodes 72 and 73 respectively may be an embodiment of these connecting electrodes.

The first and second connecting electrodes 72 and 73 and the pixel electrode 71 may be disposed in the same plane by the same process. That is, like the pixel electrode 71, the first and second connecting electrodes 72 and 73 may be transparent electrodes made of indium tin oxide (ITO) or indium zinc oxide (IZO). When the first and second connecting electrodes 72 and 73 are made of ITO or IZO, they exhibit superior contact characteristics with the gate metal patterns and the data metal patterns.

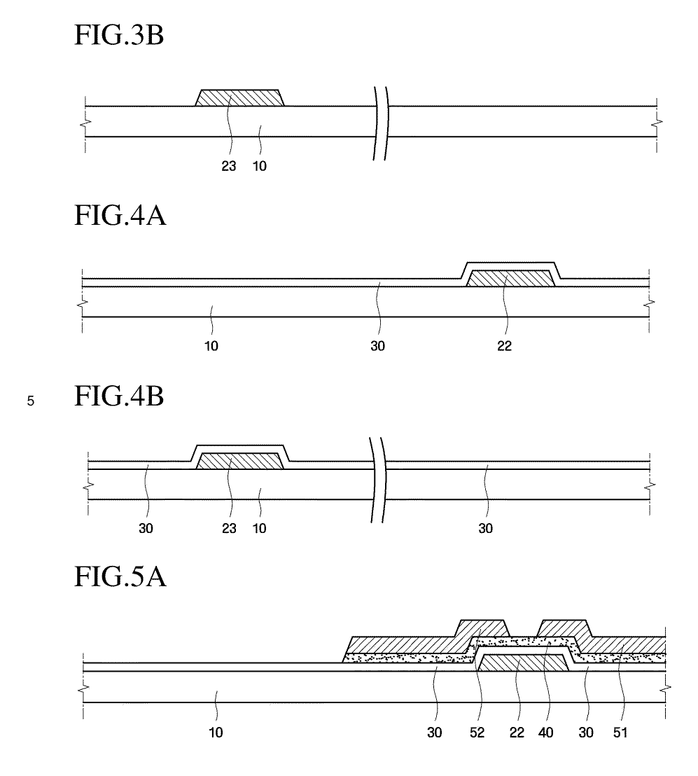

Hereinafter, a method of manufacturing the TFT substrate of FIG. 1 according to the present invention will be described in detail with reference to FIGS. 3A through 7B. FIGS. 3A through 7B are exemplary cross-sectional views for sequentially explaining processes included in the method of manufacturing the TFT substrate of FIG. 1 according to the present invention.

Referring to FIGS. 3A and 3B, a metal layer (not shown) for disposing gate wirings is stacked on the insulating substrate 10 and then patterned to form the gate electrode 22, the gate extension portion 23, and the gate metal patterns (not shown).

In one embodiment, the insulating substrate 10 may comprise soda lime glass. Soda lime glass is less expensive and an insulating substrate comprising soda lime glass can be manufactured at a lower cost than boro-silicate glass such as alkali-free glass and alumino-boro-silicate glass. However, alkali metal oxides (such as Na₂O and K₂O) added in soda lime glass disrupt the network structure of the soda lime glass by increasing the amount of non-bridging oxygen present in the insulating substrate. As a result, the melting point of the soda lime glass is lowered, and the rate of expansion or contraction of the insulating substrate in response to a change in temperature is increased. The thermal expansion coefficient of soda lime glass is 2.7 times higher than that of boro-silicate glass. If soda lime glass containing a substantial amount of alkali metal oxides is used to form the insulating substrate 10 it may bend or crack, or the wirings may be misaligned during subsequent heat treatment. For this reason, subsequent processes must be performed at a low temperature to prevent the deterioration of insulating substrates 10 that comprise soda lime glass.

In order to prevent the deterioration of the insulating substrates 10 that comprise soda lime glass, the post processing is generally conducted at low temperatures. Sputtering is a technique used to form the gate wirings on the insulating substrate 10. Sputtering can be used to form the gate wirings, which include the gate line 21, the gate electrode 22, and the gate extension portion 23. Sputtering may be performed at a low temperature of 200 degrees Celsius (“° C.”) or below. If the gate wirings are disposed by sputtering at such a low temperature, the deterioration of the insulating substrate 10 made of soda lime glass can be prevented. Next, the conductive layers are patterned by a wet-etching process or a dry-etching process. In the wet-etching process, an etchant such as phosphoric acid, nitric acid or acetic acid, may be used.

Referring to FIGS. 4A and 4B, the gate insulating film 30 is deposited on the insulating substrate 10 and on the gate wirings. The gate insulating film 30 may be made of silicon nitride and deposited by plasma enhanced chemical vapor deposition (“PECVD”) or reactive sputtering. In order to prevent the deterioration of the insulating substrate 10, the gate insulating film 30 may also be disposed at a low temperature of about 280° C. or below.

When the gate insulating film 30 is disposed at such a low temperature, its characteristics may be degraded, which not only adversely affects characteristics of a device such as a TFT but also the contact characteristics of the first through third contact holes 65 through 67 (see FIGS. 2A and 2B). Specifically, the gate insulating film 30 disposed at a low temperature may be porous and inferior in uniformity and chemical resistance. Thus, etching characteristics of the gate insulating film 30 are likely to be degraded during a subsequent ashing process.

In order to prevent the characteristics of the gate insulating film 30 from deteriorating, the types and ratio of reaction gases used to deposit the gate insulating film 30 may be appropriately controlled.

Specifically, when the gate insulating film 30 is deposited, the temperature inside a chamber may be maintained at about 280° C. or below. Then, a combination of gases, some of which are reactive, such as silane gas (SiH₄), ammonia gas (NH₃), or nitrogen gas (N₂), and hydrogen gas (H₂) may be introduced into the chamber to deposit the gate insulating film 30. Here, the hydrogen gas may be replaced with helium (He) gas or used in combination with the helium gas. In one embodiment, a volume ratio of the ammonia gas to the silane gas to the nitrogen gas may be maintained at about 1:2:2 to about 1:6:6. In an exemplary embodiment, a volume ratio of the ammonia gas to the silane gas to the nitrogen gas may be maintained at approximately 1:3:4.

A volume ratio (hydrogen/silane) of the hydrogen gas to the silane gas may be maintained at about 0.33 to about 1. When the volume ratio (hydrogen/silane) of the hydrogen gas to the silane gas is lower than about 0.33, the characteristics of the gate insulating film 30 may be degraded. When the volume ratio (hydrogen/silane) of the hydrogen gas to the silane gas is higher than about 1, deposition characteristics of the gate insulating film 30 may be degraded.

When used in an appropriate amount to deposit the gate insulating film 30, the hydrogen gas can prevent the gate insulating film 30 from being over-etched during the etching process, thereby inhibiting the formation of notches at an interface between the gate insulating film 30 and the gate wirings. That is, the addition of the hydrogen gas can enhance the interface characteristics of the gate insulating film 30 with the gate wirings and reduce the etch rate of the interface. As a result, notching can be prevented during the etching process.

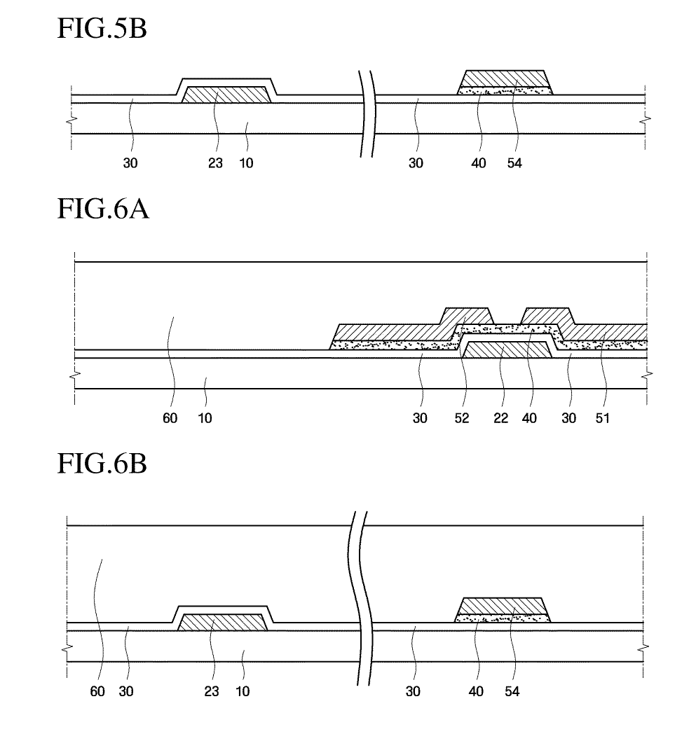

Referring to FIGS. 5A and 5B, a semiconductor material layer and a conductive layer for disposing data wirings are successively deposited on the gate insulating film 30 and then etched to form the semiconductor layer 40 and the data wirings which include the source electrode 51, the drain electrode 52, the data line 53, and the data extension portion 54.

The semiconductor material layer and the conductive layer may be successively deposited by sputtering and then etched using the same etch mask to form the semiconductor layer 40 and the data wirings. In addition, the semiconductor layer 40 and the data wirings may be successively deposited within a single vacuum chamber to prevent characteristics of the semiconductor layer 40 from being degraded by oxygen in the atmosphere.

Since the semiconductor layer 40 and the data wirings are deposited by sputtering at a low temperature, the deterioration of the insulating substrate 10 comprising soda lime glass can be prevented. Here, the semiconductor layer 40 may be an active material having conductive characteristics when a driving current is supplied to the active material and may include a semiconductor material and a metal oxide.

The semiconductor layer 40 comprise an oxide of a material selected from the group consisting of Zn, In, Ga, Sn, or a combination thereof. For example, the semiconductor layer 40 may comprise a mixed oxide selected from the group consisting of ZnO, InZnO, InGaO, InSnO, ZnSnO, GaSnO, GaZnO, GaZnSnO, GaInZnO, or a combination thereof. In particular, ZnO, InZnO, and GaInZnO are desirable. An oxide semiconductor has 5 to 6 times greater effective charge mobility than hydrogenated amorphous silicon and displays excellent semiconductor properties in terms of, for example, stability. Since the oxide semiconductor has superior ohmic contact characteristics with the data wirings, there is no need to form a separate ohmic contact layer, thereby reducing the manufacturing time.

Referring to FIGS. 6A and 6B, the passivation layer 60 is disposed on the resultant structure, that is, the gate insulating film 30 and the data wirings.

The passivation layer 60 may be made of silicon nitride and deposited by PECVD or reactive sputtering. In order to prevent the deterioration of the insulating substrate 10 according to the present embodiment, the passivation layer 60, like the gate insulating film 30, may also be disposed at a low temperature of about 280° C. or below.

If the passivation layer 60 is disposed at a low temperature, just like the gate insulating film 30, its characteristics may be degraded. In order to prevent the characteristics of the passivation layer 60 from being degraded, the types and ratio of reaction gases used during the formation of the passivation layer 60 may also be appropriately controlled.

Specifically, when the passivation layer 60 is deposited, the temperature inside a chamber may be maintained at about 280° C. or below. Then, a combination of gases, some of which are reactive, such as silane gas, ammonia gas, or nitrogen gas, and hydrogen gas may be introduced into the chamber to facilitate the deposition of the passivation layer 60. Here, the hydrogen gas may be replaced with the helium gas or used in combination with the helium gas. In one embodiment, a volume ratio of the ammonia gas to the silane gas to the nitrogen gas may be maintained at about 1:2:2 to about 1:6:6. In an exemplary embodiment, a volume ratio of the ammonia gas to the silane gas to the nitrogen gas may be maintained at approximately 1:3:4. A volume ratio (hydrogen/silane) of the hydrogen gas to the silane gas may be maintained at about 0.33 to about 1. When the volume ratio (hydrogen/silane) of the hydrogen gas to the silane gas is lower than about 0.33, the characteristics of the passivation layer 60 may be degraded. When the volume ratio (hydrogen/silane) of the silane gas to the hydrogen gas is higher than about 1, deposition characteristics of the passivation layer 60 may be degraded.

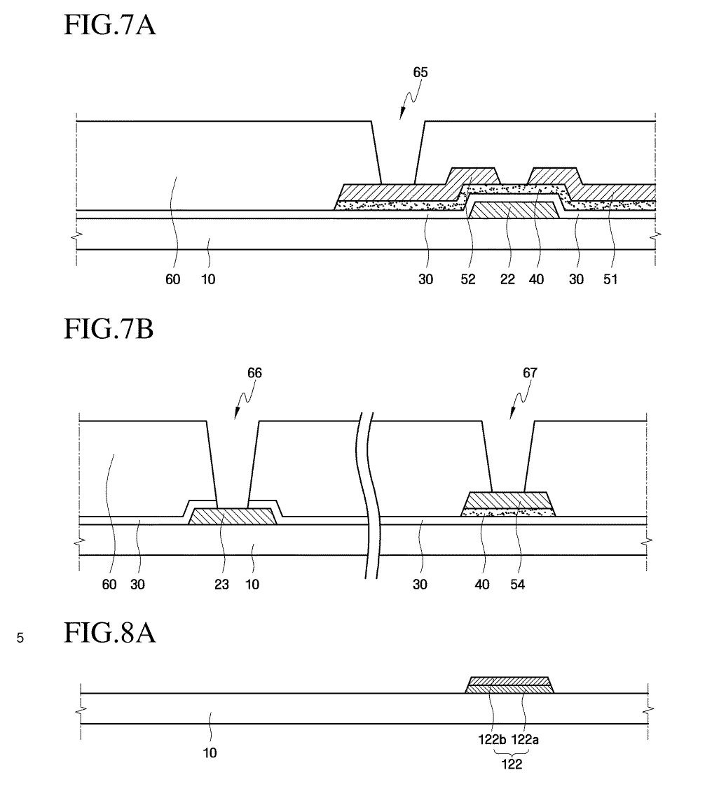

Referring to FIGS. 7A and 7B, the passivation layer 60 is coated with a photosensitive film. Thereafter, the photosensitive film is exposed to light using an optical mask and then developed to form the first through third contact holes 65 through 67. While only the first through third contact holes 65 through 67 are illustrated in FIGS. 7A and 7B, a plurality of contact holes may be formed to connect the gate metal patterns (not shown) to the data metal patterns (not shown) as described above.

The first through third contact holes 65 through 67 may be formed by a dry-etching process. An etching gas used in the dry-etching process may be O₂ mixed with CF₄, CHF₃, CH₂F₂, CH₃F, C₂F₆, SF₆, and CₙFₙ₊₄. Since the dry-etching process can be performed as anisotropic etching, notching in the gate insulating film 30 and the passivation layer 60 can be minimized or prevented.

Pressure and plasma power may be controlled to enhance characteristics of etched surfaces of the first through third contact holes 65 through 67. Specifically, when the first through third contact holes 65 through 67 are formed, the pressure within a chamber must be maintained at about 60 mT or below. When the pressure within the chamber exceeds about 60 mT during the dry-etching process, tips may protrude from sides of the gate insulating film 30 and the passivation layer 60. Thus, the pressure within the chamber should be maintained at about 60 mT or below during the dry-etching process.

On the other hand, too low pressure within the chamber may degrade etching efficiency or anisotropic etching characteristics. Hence, the pressure within the chamber must be at least about 10 mT. Optimal pressure within the chamber may range from about 40 to about 60 mT. In addition, plasma power for etching may be maintained at about 7000 W or below.

Referring to FIGS. 2A and 2B, a transparent metal layer is deposited on the passivation layer 60 and then etched to form the pixel electrode 71, the first connecting electrode 72, and the second connecting electrode 73.

The pixel electrode 71, the first connecting electrode 72, and the second connecting electrode 73 are connected to the drain electrode 52, the gate extension portion 23, and the data extension portion 54 by the first through third contact holes 65 through 67, respectively. A plurality of connecting electrodes (not shown) may be disposed in the same plane as the pixel electrode 71, the first connecting electrode 72, and the second connecting electrode 73. The connecting electrodes may form various circuit units together with the gate metal patterns (not shown) and the data metal patterns (not shown).

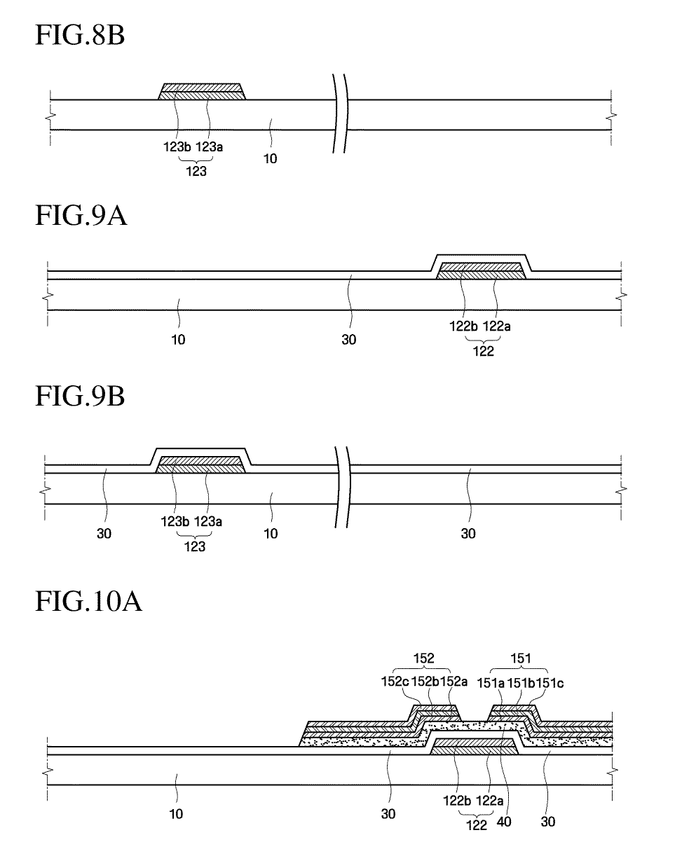

Hereinafter, a method of manufacturing a TFT substrate according to another embodiment of the present invention will be described in detail with reference to FIGS. 8A through 13. FIGS. 8A through 13B are exemplary cross-sectional views for sequentially explaining processes included in the method of manufacturing the TFT substrate according to the present invention. Elements substantially identical to those of the previous embodiment are indicated by like reference numerals, and thus their description will be omitted.

Referring to FIGS. 8A and 8B, a metal layer (not shown) for disposing gate wirings is stacked on an insulating substrate 10 and then patterned to form gate wirings, which include a gate line (not shown), a gate electrode 122, a gate extension portion 123, and gate metal patterns (not shown).

The gate wirings (i.e., the gate electrode 122 and the gate extension portion 123) may be a dual layer including a lower layer and an upper layer. For example, the gate electrode 122 may include a gate electrode lower layer 122a and a gate electrode upper layer 122b, and the gate extension portion 123 may include a gate extension portion lower layer 123a and a gate extension portion upper layer 123b.

The gate wirings may be made of Ta/Al, Ta/Al, Ni/Al, Co/Al, or Mo (a Mo alloy)/Cu. For example, the gate electrode lower layer 122a and the gate extension portion lower layer 123a may be made of aluminum, and the gate electrode upper layer 122b and the gate extension portion upper layer 123b may be made of molybdenum. The gate electrode upper layer 122b and the gate extension portion upper layer 123b made of molybdenum exhibit superior contact characteristics with ITO or IZO, thereby enhancing contact characteristics of the gate electrode 122 and the gate extension portion 123 with connecting electrodes. This will be described in detail later.

Next, sputtering may be performed to form the gate electrode 122 and the gate extension portion 123. Sputtering may be performed at a low temperature of about 200° C. or below. If the gate electrode 122 and the gate extension portion 123 are disposed by sputtering at such a low temperature, the deterioration of the insulating substrate 10 made of soda lime glass can be prevented. Next, the conductive layers are patterned by a wet-etching process or a dry-etching process. In the wet-etching process, an etchant, such as phosphoric acid, nitric acid or acetic acid, may be used.

Referring to FIGS. 9A and 9B, a gate insulating film 30 is deposited on the insulating substrate 10, the gate electrode 122, and the gate extension portion 123. The gate insulating film 30 may be made of silicon nitride and deposited by PECVD or reactive sputtering. In order to prevent the deterioration of the insulating substrate 10 according to the present embodiment, the gate insulating film 30 may also be disposed at a low temperature of about 280° C. or below.

To prevent the characteristics of the gate insulating film 30 from deteriorating, the types and ratio of reaction gases used to deposit the gate insulating film 30 may be controlled appropriately.

Specifically, when the gate insulating film 30 is deposited, the temperature inside a chamber may be maintained at about 280° C. or below. Then, a combination of gases, some of which may be reactive gases, such as silane gas, ammonia gas, or nitrogen gas, and hydrogen gas may be introduced into the chamber to deposit the gate insulating film 30. Here, the hydrogen gas may be replaced with the helium gas or used in combination with the helium gas. In one embodiment, a volume ratio of the ammonia gas to the silane gas to the nitrogen gas may be maintained at about 1:2:2 to about 1:6:6. In an exemplary embodiment, a volume ratio of the ammonia gas to the silane gas to the nitrogen gas may be maintained at approximately 1:3:4. A volume ratio (hydrogen/silane) of the silane gas to the hydrogen gas may be maintained at about 0.33 to about 1. When the volume ratio (hydrogen/silane) of the silane gas to the hydrogen gas is lower than about 0.33, the characteristics of the gate insulating film 30 may be degraded. When the volume ratio (hydrogen/silane) of the silane gas to the hydrogen gas is higher than about 1, deposition characteristics of the gate insulating film 30 may be degraded.

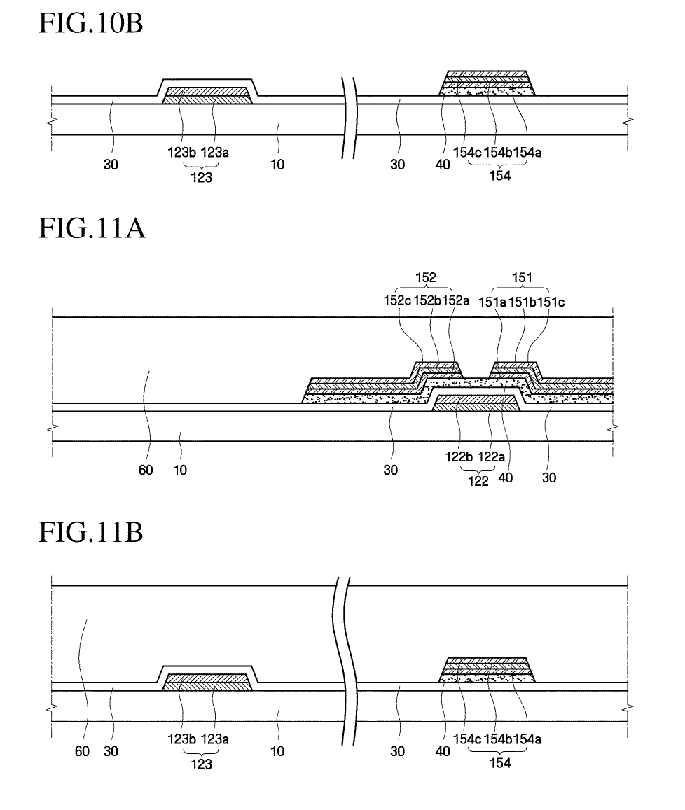

Referring to FIGS. 10A and 10B, a semiconductor material layer and a conductive layer for disposing data wirings are successively deposited on the gate insulating film 30 and then etched to form a semiconductor layer 40 and data wirings. The data wirings include a source electrode 151, a drain electrode 152, and a data extension portion 154.

The semiconductor material layer and the conductive layer may be successively deposited by sputtering and then etched using the same etch mask to form the semiconductor layer 40 and the data wirings. In addition, the semiconductor layer 40 and the data wirings may be successively deposited within a single vacuum chamber to prevent characteristics of the semiconductor layer 40 from being degraded by oxygen in the atmosphere.

The data wirings (i.e., the source electrode 151, the drain electrode 152, and the data extension portion 154) may be a triple layer including a lower layer, an intermediate layer, and an upper layer. For example, the data wirings may be made of titanium/aluminum/titanium (Ti/Al/Ti), tantalum/aluminum/tantalum (Ta/Al/Ta), titanium/aluminum/titanium nitride (Ti/Al/TiN), tantalum/aluminum/tantalum nitride (Ta/Al/TaN), nickel/aluminum/nickel (Ni/Al/Ni), cobalt/aluminum/cobalt (Co/Al/Co), molybdenum/aluminum/molybdenum (Mo/Al/Mo), or chromium/aluminum/chromium (Cr/Al/Cr). For example, lower layers 151a, 152a, and 154a of the data wirings may be made of molybdenum, intermediate layers 151b, 152b, and 154b of the data wirings may be made of aluminum, and upper layers 151c, 152c, and 154c of the data wirings may be made of molybdenum. The upper layers 151c, 152c, and 154c made of molybdenum exhibit superior contact characteristics with ITO or IZO, thereby enhancing contact characteristics of the data wirings with connecting electrodes. This will be described in detail later. The data wirings are not necessarily a triple layer and may also be a dual layer including molybdenum and aluminum.

Referring to FIGS. 11A and 11B, a passivation layer 60 is disposed on the resultant structure, that is, the gate insulating film 30 and the data wirings.

The passivation layer 60 may be made of silicon nitride and deposited by PECVD or reactive sputtering. In order to prevent the deterioration of the insulating substrate 10, the passivation layer 60, like the gate insulating film 30, may also be disposed at a low temperature of about 280° C. or below.

When the passivation layer 60 is deposited, the temperature inside a chamber may be maintained at about 280° C. or below. Then, a combination of gases, some of which may be reactive gases, such as silane gas, ammonia gas, or nitrogen gas, and hydrogen gas may be introduced into the chamber to deposit the passivation layer 60. Here, the hydrogen gas may be replaced with the helium gas or used in combination with the helium gas. In one embodiment, a volume ratio of the ammonia gas to the silane gas to the nitrogen gas may be maintained at about 1:2:2 to about 1:6:6. In an exemplary embodiment, a volume ratio of the ammonia gas to the silane gas to the nitrogen gas may be maintained at approximately 1:3:4. A volume ratio (hydrogen/silane) of the hydrogen gas to the silane gas may be maintained at about 0.33 to about 1. When the volume ratio (hydrogen/silane) of the hydrogen gas to the silane gas is lower than about 0.33, characteristics of the passivation layer 60 may be degraded. When the volume ratio (hydrogen/silane) of the hydrogen gas to the silane gas is higher than about 1, deposition characteristics of the passivation layer 60 may be degraded.

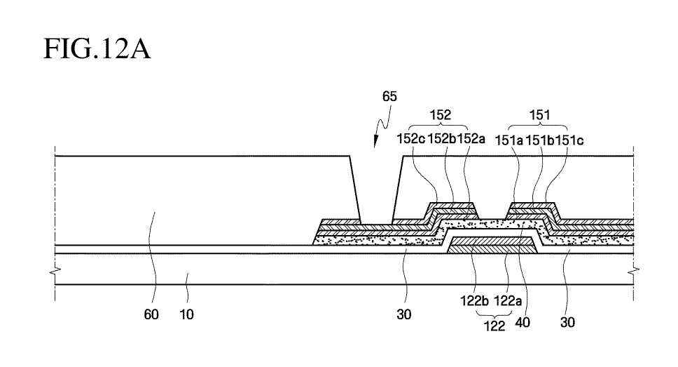

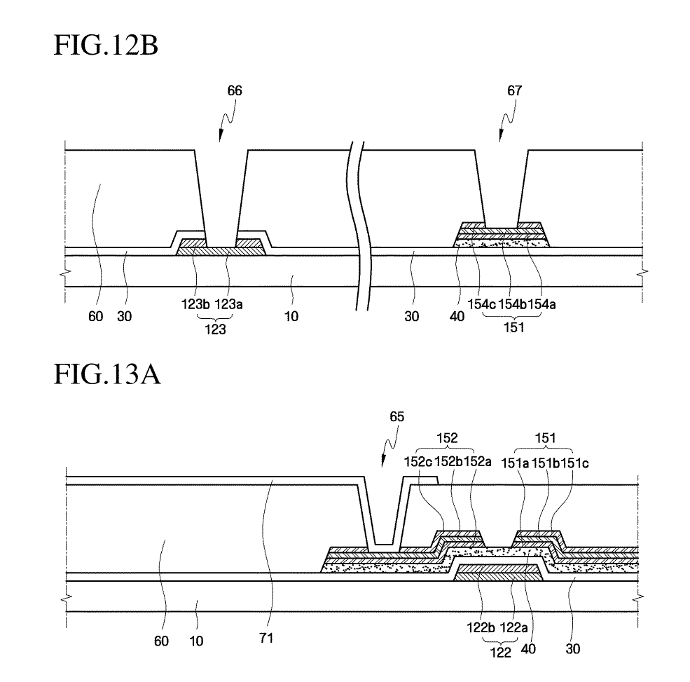

Referring to FIGS. 12A and 12B, the passivation layer 60 is coated with a photosensitive film. Thereafter, the photosensitive film is exposed to light using an optical mask and then developed to form first through third contact holes 65 through 67. While only the first through third contact holes 65 through 67 are illustrated in FIGS. 12A and 12B, a plurality of contact holes may be formed to connect the gate metal patterns (not shown) to the data metal patterns (not shown) as described above. The first through third contact holes 65 through 67 may be formed by a dry-etching process. An etching gas used in the dry-etching process may be O₂ mixed with CF₄, CHF₃, CH₂F₂, CH₃F, C₂F₆, SF₆, and CₙFₙ₊₄. Since the dry-etching process can be performed as anisotropic etching, notching in the gate insulating film 30 and the passivation layer 60 can be minimized or prevented.

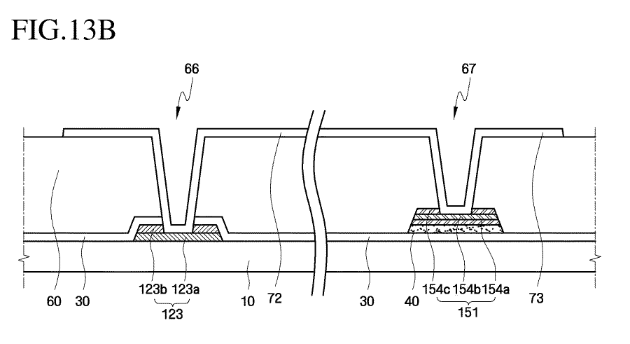

The upper molybdenum layers of the gate wirings (i.e., the gate electrode 122 and the gate extension portion 123) and the data wirings (i.e., the source electrode 151, the drain electrode 152, and the data extension portion 154) may be etched simultaneously by the dry-etching process. Accordingly, the intermediate aluminum layers of the gate wrings and the data wirings may be exposed. Since the aluminum layers have inferior ohmic characteristics when contacted with ITO and IZO, the upper molybdenum layers may be in ohmic contact with first and second connecting electrodes 72 and 73 (see FIGS. 13A and 13B). Thus, the shape of etched surfaces of the first through third contact holes 65 through 67 may affect ohmic contact characteristics between the first and second connecting electrodes 72 and 73 and the data wirings.

Pressure and plasma power may be controlled to enhance characteristics of the etched surfaces of the first through third contact holes 65 through 67. Specifically, when the first through third contact holes 65 through 67 are formed, the pressure within a chamber must be maintained at about 60 mT or below but must be at least about 10 mT. Optimal pressure within the chamber may range from about 40 to about 60 mT. In addition, plasma power for etching may be maintained at about 7000 W or below.

Referring to FIGS. 13A and 13B, a transparent metal layer is deposited on the passivation layer 60 and then etched to form a pixel electrode 71, the first connecting electrode 72, and the second connecting electrode 73.

The pixel electrode 71, the first connecting electrode 72, and the second connecting electrode 73 are connected to the drain electrode 152, the gate extension portion 123, and the data extension portion 154 by the first through third contact holes 65 through 67, respectively. A plurality of connecting electrodes (not shown) may be disposed in the same plane as the pixel electrode 71, the first connecting electrode 72, and the second connecting electrode 73. The connecting electrodes may form various circuit units together with the gate metal patterns (not shown) and the data metal patterns (not shown).

While the present invention has been particularly shown and described with reference to exemplary embodiments thereof, it will be understood by those of ordinary skill in the art that various changes in form and detail may be made therein without departing from the spirit and scope of the present invention as defined by the following claims. The exemplary embodiments should be considered in a descriptive sense only and not for purposes of limitation.

What is claimed is:

1. A method of manufacturing a thin-film transistor substrate, the method comprising:
disposing a gate wiring on an insulating substrate;
disposing a gate insulating film on the gate wiring;
disposing a data wiring on the gate insulating film;
disposing a passivation layer on the data wiring; and
forming a contact hole by etching at least one of the gate insulating film and the passivation layer,
wherein at least one of the gate insulating film and the passivation layer is disposed at a temperature of about 280° C. or below, and the forming of the contact hole is performed at a pressure of about 60 mT or below.

2. The method of claim 1, wherein at least one of the disposing of the gate insulating film or the disposing of the passivation layer is conducted in the presence of silane gas and hydrogen gas.

3. The method of claim 2, wherein a volume ratio of the hydrogen gas to the silane gas is about 0.33 to about 1.

4. The method of claim 3, wherein at least one of the disposing of the gate insulating film and the disposing of the passivation layer further is conducted in the presence of nitrogen gas and ammonia gas.

5. The method of claim 4, wherein a volume ratio of the ammonia gas to the silane gas to the nitrogen gas is about 1:3:4.

6. The method of claim 1, wherein the contact hole is formed at a pressure of about 40 to about 60 mT.

7. The method of claim 1, wherein at least one of the gate insulating film and the passivation layer comprises silicon nitride or silicon oxide.

8. The method of claim 1, wherein at least one of the gate wiring and the data wiring is a multilayer that comprises aluminum and molybdenum.

9. The method of claim 1, wherein the insulating substrate comprises soda lime glass.

10. The method of claim 1, further comprising disposing an electrode layer, which contacts at least one of the gate wiring and the data wiring through the contact hole.

11. A method of manufacturing a thin film transistor substrate, the method comprising:
disposing a gate wiring on an insulating substrate;
disposing a gate insulating film on the gate wiring;
disposing a data wiring on the gate insulating film;
disposing a passivation layer on the data wiring; and
forming a contact hole by etching at least one of the gate insulating film and the passivation layer,
wherein at least one of the gate insulating film and the passivation layer is disposed at a temperature of about 280° C. or below in the presence of hydrogen gas and a silane gas;
wherein the volume ratio of the hydrogen gas to the silane gas is about 0.33 to about 1.

12. The method of claim 11, wherein at least one of the disposing of the gate insulating film and the disposing of the passivation layer is further conducted in the presence of nitrogen gas and ammonia gas.

13. The method of claim 12, wherein a volume ratio of the ammonia gas to the silane gas to the nitrogen gas is about 1:3:4.

14. The method of claim 11, wherein the contact hole is formed at a pressure of about 40 to about 60 mT.

15. The method of claim 11, wherein at least one of the gate insulating film and the passivation layer comprises silicon nitride or silicon oxide.

16. The method of claim 11, wherein at least one of the gate wiring and the data wiring is a multilayer that comprises aluminum and molybdenum.

17. The method of claim 11, wherein the insulating substrate comprises soda lime glass.

18. The method of claim 11, further comprising disposing an electrode layer, which contacts at least one of the gate wiring and the data wiring through the contact hole.
